(19) United States
(12) Patent Application Publication
(10) Pub. No.: US 2010/0062549 A1
(43) Pub. Date: Mar. 11, 2010

(54) PATTERN CORRECTING METHOD, METHOD OF MANUFACTURING SEMICONDUCTOR DEVICE, AND PATTERN CORRECTING PROGRAM

(76) Inventor: Shimon MAEDA, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/549,209

(22) Filed: Aug. 27, 2009

(30) Foreign Application Priority Data
Sep. 10, 2008 (JP) 2008-232064

(51) Int. Cl. H01L 21/66; G06F 17/50

(52) U.S. Cl. 438/14; 716/19; 257/E21.53

(57) ABSTRACT

A side of a correction target pattern is divided into a plurality of segments. A space between each of the divided segments or an imaginary segment extended from both the ends of the segment to outer sides and a side of an adjacent pattern adjacent to the segment is measured. An overlapping distance between each of the divided segments or the imaginary segment extended from both the ends of the segment to the outer sides and the side of the adjacent pattern is measured. A shift amount of the segment is corrected based on the overlapping distance.

### CROSS-REFERENCE TO RELATED APPLICATION

This application claims the benefit of priority from Japanese Patent Application No. 2008-232064, filed on Sep. 10, 2008, the entire contents of which are incorporated herein by reference.

### BACKGROUND OF THE INVENTION

1. Field of the Invention

The present invention relates to a pattern correcting method, a method of manufacturing a semiconductor device, and a pattern correcting program, and, more particularly, is suitably applied to a pattern correcting method for relaxing fluctuation in exposure intensity during photolithography due to the density of a mask pattern.

2. Description of the Related Art

According to the refining of semiconductor integrated circuits in recent years, patterns equal to or smaller than a half of the wavelength of light is formed by photolithography. In this case, an error between a dimension of patterns actually formed on a wafer and a design value is large. Therefore, the dimension of the patterns actually formed on the wafer is set closer to the design value by predicting such an error with computer simulation and applying optical proximity correction (OPC) to a mask pattern.

A degree of optical proximity effect fluctuates according to the density of patterns. For example, in an isolated pattern, the influence of the optical proximity effect is large. Therefore, when the isolated pattern is corrected, it is necessary to increase a bias (a shift amount) of a segment given to the isolated pattern. As a method of determining the density of patterns, a method of measuring spaces among the patterns is generally used. However, when the spaces among the patterns are measured in one place, errors among correction values of the patterns are large if the patterns overlap only partially.

Therefore, Japanese Patent Application Laid-Open No. 2007-121549 discloses a method of dividing a side of a pattern into a plurality of sides according to design data of an integrated circuit device, measuring, for each of the divided sides, the width of a pattern corresponding to the side and a space to a pattern adjacent to the pattern corresponding to the side in a plurality of places, extracting a plurality of shift amounts referring to a correction table based on a result of the measurement, and calculating correction values of the divided sides based on the extracted shift amounts.

However, simply by measuring spaces among patterns in a plurality of places, a degree of overlapping distance of the patterns cannot be taken into account. Errors among correction values of the patterns are large depending on a layout of the patterns.

### BRIEF SUMMARY OF THE INVENTION

A pattern correcting method according to an embodiment of the present invention comprises: dividing a side of a correction target pattern into a plurality of segments; measuring a space between each of the divided segment or an imaginary segment extended from both ends of the segment to outer sides and a side of an adjacent pattern adjacent to the segment; measuring an overlapping distance between each of the divided segment or the imaginary segment extended from both the ends of the segment to the outer sides and the side of the adjacent pattern; extracting a shift amount of the segment corresponding to the measured space; and calculating a correction value for the segment by correcting the shift amount based on the overlapping distance.

A pattern correcting method according to an embodiment of the present invention comprises: dividing a side of a correction target pattern into a plurality of segments; measuring a space between each of the divided segment or an imaginary segment extended from both ends of the segment to outer sides and a side of an adjacent pattern adjacent to the segment; giving attributes to the divided segment; measuring an overlapping distance between each of the divided segment or the imaginary segment extended from both the ends of the segment to the outer sides and the side of the adjacent pattern; extracting a shift amount of the segment corresponding to the measured space; selecting a correction value calculation formula corresponding to each of the attributes; and calculating a correction value for the segment by correcting the shift amount on the correction value calculation formula based on the overlapping distance.

A pattern correcting method according to an embodiment of the present invention comprises: dividing a side of a correction target pattern into a plurality of segments; measuring a space between each of the divided segment or an imaginary segment extended from both ends of the segment to outer sides and a side of an adjacent pattern adjacent to the segment and line width of the segment; measuring an overlapping distance between each of the divided segment or the imaginary segment extended from both the ends of the segment to the outer sides and the side of the adjacent pattern; extracting a shift amount of the segment corresponding to the measured space and the measured line width; and calculating a correction value for the segment by correcting the shift amount based on the overlapping distance.

A pattern correcting method according to an embodiment of the present invention comprises: dividing a side of a correction target pattern into a plurality of segments; finding, in a range of a predetermined radiation angle from a point on the segment, a side of an adjacent pattern adjacent to each of the divided segment; measuring a space between the found side of the adjacent pattern and the segment; extracting a shift amount corresponding to the measured space; and calculating a correction value for the segment by correcting the shift amount based on a range of angle formed by segments crossing the found side of the adjacent pattern among segments extended in the range of the predetermined radiation angle from the point on the segment.

A method of manufacturing a semiconductor device according to an embodiment of the present invention comprises: dividing a side of a correction target pattern into a plurality of segments; measuring a space between each of the divided segment or an imaginary segment extended from both ends of the segment to outer sides and a side of an adjacent pattern adjacent to the segment; measuring an overlapping distance between each of the divided segment or the imaginary segment extended from both the ends of the segment to the outer sides and the side of the adjacent pattern; extracting a shift amount of the segment corresponding to the measured space; calculating a correction value for the segment by correcting the shift amount based on the overlapping distance; and transferring, using a mask formed based on a mask pattern corrected based on the correction value, the mask pattern onto a semiconductor substrate.

A pattern correcting program for correcting, based on an overlapping distance between a segment on a correction target pattern and a side of an adjacent pattern adjacent to the segment or an imaginary segment extended from both ends of the segment to outer sides, a shift amount determined depending on a space between the segment or the imaginary segment extended from both the ends of the segment to the outer sides and the side of the adjacent pattern to thereby calculate a correction value for the segment.

### BRIEF DESCRIPTION OF THE DRAWINGS

FIG. 1 is a block diagram of a schematic configuration of a pattern correction processing apparatus according to a first embodiment of the present invention;

FIG. 2 is a plan view of an example of a layout of patterns for explaining pattern correction processing according to a second embodiment of the present invention;

FIG. 3 is a plan view of an example of a layout of patterns for explaining pattern correction processing according to a third embodiment of the present invention;

FIG. 4 is a diagram of an example of a correction table used for pattern correction processing according to an embodiment of the present invention;

FIG. 5 is a flowchart of an example of pattern correction processing executed by the pattern correction processing apparatus shown in FIG. 1;

FIG. 6A is a plan view of an example of corrected patterns according to an embodiment of the present invention;

FIG. 6B is a plan view of another example of corrected patterns according to the embodiment of the present invention;

FIG. 7 is a plan view of an example of a layout of patterns for explaining pattern correction processing according to a fourth embodiment of the present invention;

FIG. 8 is a plan view of an example of a layout of patterns for explaining pattern correction processing according to a fifth embodiment of the present invention;

FIG. 9 is a plan view of an example of division of sides of a pattern for explaining pattern correction processing according to a sixth embodiment of the present invention;

FIG. 10 is a plan view of an example of attributes given to segments obtained by dividing the sides of the pattern shown in FIG. 9;

FIG. 11A is a plan view of an example of pattern correction processing executed when an attribute of an inner corner is given to a segment according to a seventh embodiment of the present invention;

FIG. 11B is a plan view of another example of the pattern correction processing executed when the attribute of the inner corner is given to the segment according to the seventh embodiment;

FIG. 12A is a plan view of an example of pattern correction processing executed when an attribute of an outer corner is given to a segment according to an eighth embodiment of the present invention;

FIG. 12B is a plan view of another example of the pattern correction processing executed when the attribute of the outer corner is given to the segment according to the eighth embodiment;

FIG. 13 is a plan view of an example of pattern correction processing executed when an attribute is given to a segment according to a ninth embodiment of the present invention;

FIG. 14 is a plan view of an example of pattern correction processing executed when an attribute is given to a segment according to a tenth embodiment of the present invention;

FIG. 15 is a flowchart of an example of pattern correction processing executed when an attribute is given to a segment in the pattern correction processing apparatus shown in FIG. 1;

FIG. 16A is a sectional view of a method of manufacturing a semiconductor device according to an eleventh embodiment of the present invention;

FIG. 16B is a sectional view of the method of manufacturing a semiconductor device according to the eleventh embodiment;

FIG. 16C is a sectional view of the method of manufacturing a semiconductor device according to the eleventh embodiment; and

FIG. 16D is a sectional view of the method of manufacturing a semiconductor device according to the eleventh embodiment.

### DETAILED DESCRIPTION OF THE INVENTION

Exemplary embodiments of the present invention are explained in detail below. The present invention is not limited by the embodiments.

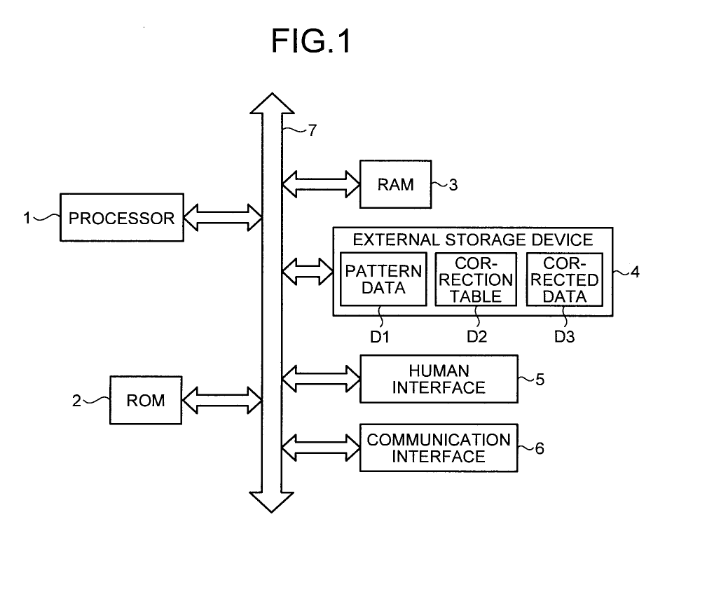

FIG. 1 is a block diagram of a schematic configuration of a pattern correction processing apparatus according to a first embodiment of the present invention.

In FIG. 1, the pattern correction processing apparatus can include a processor 1 including a central processing unit (CPU), a read only memory (ROM) 2 that stores stationary data, a random access memory (RAM) 3 that provides the processor 1 with a work area and the like, an external storage device 4 that stores a program for actuating the processor 1 and various data, a human interface 5 that mediates between a person and a computer, and a communication interface 6 that provides communication means with the outside. The processor 1, the ROM 2, the RAM 3, the external storage device 4, the human interface 5, and the communication interface 6 are connected via a bus 7.

Pattern data D1, a correction table D2, and corrected data D3 are stored in the external storage device 4. The pattern data D1 can be design data concerning a layout of a semiconductor integrated circuit or can be data obtained by processing a figure represented by the design data. In the correction table D2, a bias (a shift amount) corresponding to a space between a segment on a correction target pattern and a side of an adjacent pattern adjacent to the segment can be registered. In the corrected data D3, data corrected based on a correction value calculated from a bias extracted from the correction table D2 can be registered.

The processor 1 can calculate the corrected data D3 from the pattern data D1 by executing a pattern correcting program. The program executed by the processor 1 can be stored in the external storage device 4 and read in the RAM 3 when the program is executed, can be stored in the ROM 2 in advance, or can be acquired via the communication interface 6.

As the external storage device 4, for example, magnetic disks such as a hard disk, optical disks such as a digital versatile disk (DVD), and portable semiconductor storage devices such as a USB memory and a memory card can be used. As the human interface 5, for example, a keyboard and a mouse as input interfaces and a display and a printer as output interfaces can be used. As the communication interface 6, for example, a local area network (LAN) card, a modem, and a router for connection to the Internet and a LAN can be used.

When the pattern correcting program is started, the processor 1 can set a correction target pattern from the pattern data D1 and calculate an overlapping distance between a segment on the correction target pattern and a side of an adjacent pattern adjacent to the segment. The processor 1 can extract a bias corresponding to a space between the segment on the correction target pattern and the adjacent pattern referring to the correction table D2. The processor 1 can calculate a correction value for the segment by correcting the bias based on the overlapping distance between the segment on the correction target pattern and the adjacent pattern. The processor 1 can calculate the corrected data D3 by correcting the pattern data D1 based on the correction value and store the corrected data D3 in the external storage device 4. The overlapping distance refers to, when an overlapping section is present between the segment on the correction target pattern and a side on the adjacent pattern, a distance obtained by measuring the overlapping section along the side on the adjacent pattern.

This makes it possible to apply weighting corresponding to the overlapping distance to the bias corresponding to the space between the segment on the correction target pattern and the adjacent pattern. Therefore, it is possible to give the bias to the segment on the correction target pattern while taking into account a degree of overlapping distance of the correction target pattern and the adjacent pattern. Even when the overlapping distance between the correction target pattern and the adjacent pattern changes, it is possible to reduce errors among correction values of patterns.

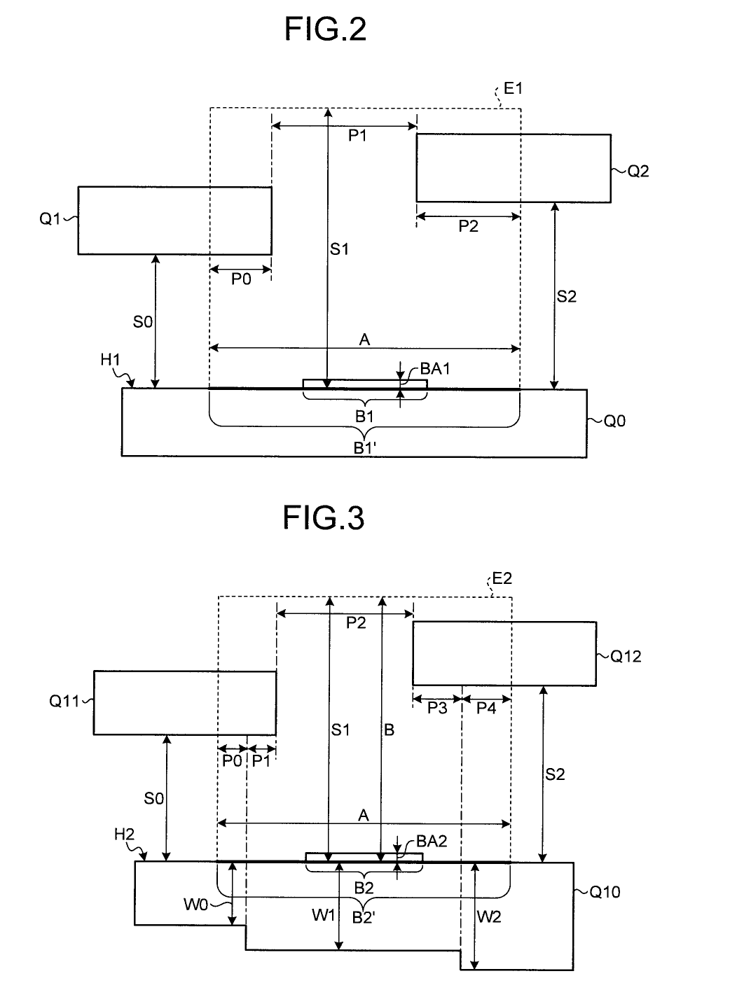

FIG. 2 is a plan view of an example of a layout of patterns for explaining pattern correction processing according to a second embodiment of the present invention.

In FIG. 2, adjacent patterns Q1 and Q2 adjacent to a correction target pattern Q0 are arranged around the correction target pattern Q0. In correcting the correction target pattern Q0, the processor 1 shown in FIG. 1 divides a side H1 of the correction target pattern Q0 into a plurality of segments. In dividing the side H1 of the correction target pattern Q0 into a plurality of segments, the processor 1 can divide the side H1 at intervals equal to or larger than a minimum design dimension of a line in design data. For example, when the minimum design dimension is 80 nanometers, the processor 1 can divide the side H1 at intervals equal to or larger than 80 nanometers. When the length of the remaining side is reduced to be equal to or smaller than the minimum design dimension by the division, the processor 1 can prevent that section from being divided. The division is not limited to division at equal intervals. The side H1 can be divided at different lengths.

In calculating a correction value for a segment B1 on the side H1, the processor 1 sets a search area E1 for the adjacent patterns Q1 and Q2 corresponding to the segment B1. In a direction parallel to the segment B1, the processor 1 can set the search area E1 to extend to outer sides from both the ends of the segment B1. In a direction perpendicular to the segment B1, the processor 1 can set the search area E1 to be larger than a maximum distance between adjacent patterns in design. However, in pattern correcting methods according to this embodiment and embodiments explained below, it is not always necessary to specify the search area E1 by extending a segment as a correction target (in this embodiment, the segment B1). For example, the processor 1 can also match both the ends of the correction target segment with both the ends of the search area E1 without extending the correction target segment.

When the search area E1 is set, the processor 1 sets, with respect to the correction target pattern Q0, an imaginary segment B1′ extended from both the ends of the segment B1 to boundaries of the search area E1. In the search area E1, the processor 1 finds the adjacent patterns Q1 and Q2 having sides overlapping the imaginary segment B1′. The processor 1 measures spaces between the imaginary segment B1′ and the sides of the adjacent patterns Q1 and Q2 and measures overlapping distances between the imaginary segment B1 and the sides of the adjacent patterns Q1 and Q2.

The processor 1 extracts biases corresponding to the spaces between the imaginary segment B1′ and the sides of the adjacent patterns Q1 and Q2 referring to the correction table D2. The processor 1 calculates a correction value BA1 for the segment B1 by correcting the biases based on the overlapping distances between the imaginary segment B1′ and the sides of the adjacent patterns Q1 and Q2. As a method of correcting, based on the overlapping distances, the biases corresponding to the spaces between the imaginary segment B1′ and the sides of the adjacent patterns Q1 and Q2, values obtained by weighting the biases with the overlapping distances can be used. The processor 1 calculates the corrected data D3 by correcting the correction target pattern Q0 based on the correction value and stores the corrected data D3 in the external storage device 4.

Consequently, even when the adjacent patterns Q1 and Q2 are present on the outer sides of both the ends of the segment B1, it is possible to give a bias to the segment B1 on the correction target pattern Q0 while taking into account spaces between the correction target pattern Q0 and the adjacent patterns Q1 and Q2. It is possible to improve accuracy of a correction value for the correction target pattern Q0.

The length in the horizontal direction of the search area E1 is represented as A, the length in the vertical direction of the search area E1 is represented as S1, a space between the correction target pattern Q0 and the adjacent pattern Q1 is represented as S0, a space between the correction target pattern Q0 and the adjacent pattern Q2 is represented as S2, an overlapping distance between the imaginary segment B1′ and the side of the adjacent pattern Q1 is represented as P0, an overlapping distance between the imaginary segment B1′ and the side of the adjacent pattern Q2 is represented as P2, and a space between the adjacent patterns Q1 and Q2 is represented as P1. A correction value Bias can be given by, for example, the following Formula (1):

Bias=Bias(So)*P0/A+Bias(S1)*P1/A+Bias(S2)*P2/A (1)

where, Bias(S0) is a bias at the space S0 between patterns, Bias(S1) is a bias at the space S1 between patterns, and Bias(S2) is a bias at the space S2 between patterns.

FIG. 3 is a plan view of an example of a layout of a pattern for explaining pattern correction processing according to a third embodiment of the present invention.

In FIG. 3, adjacent patterns Q11 and Q12 adjacent to a correction target pattern Q10 are arranged around the correction target pattern Q10. The correction target pattern Q10 includes sections having different widths. In correcting the correction target pattern Q10, the processor 1 shown in FIG. 1 divides a side H2 of the correction target pattern Q10 into a plurality of segments. In calculating a correction value for a segment B2 on the side H2, the processor 1 sets a search area E2 for the adjacent patterns Q11 and Q12 corresponding to the segment B2. In a direction parallel to the segment B2, the processor 1 can set the search area E2 to extend to outer sides from both the ends of the segment B2. In a direction perpendicular to the segment B2, the processor 1 can set the search area E2 to be larger than a maximum distance between adjacent patterns in design.

When the search area E2 is set, the processor 1 sets, with respect to the correction target pattern Q10, an imaginary segment B2′ extended from both the ends of the segment B2 to boundaries of the search area E2. In the search area E2, the processor 1 finds the adjacent patterns Q11 and Q12 having sides overlapping the imaginary segment B2′. The processor 1 measures spaces between the imaginary segment B2′ and the sides of the adjacent patterns Q11 and Q12. The processor 1 measures overlapping distances between the imaginary segment B2′ and the sides of the adjacent patterns Q11 and Q12 and measures the width of the correction target pattern Q10 for each of areas in which the imaginary segment B2′ overlaps the sides of the adjacent patterns Q11 and Q12.

The processor 1 extracts biases corresponding to the spaces between the imaginary segment B2′ and the sides of the adjacent patterns Q11 and Q12 and the width of the correction target pattern Q10 referring to the correction table D2. The processor 1 calculates a correction value BA2 for the segment B2 by correcting the biases based on the overlapping distances between the imaginary segment B2′ and the sides of the adjacent patterns Q11 and Q12. The processor 1 calculates the corrected data D3 by correcting the correction target pattern Q10 based on the correction value and stores the corrected data D3 in the external storage device 4.

Consequently, even when the width of the correction target pattern Q10 changes, it is possible to give a bias to the segment B2 on the correction target pattern Q10 while taking into account spaces between the correction target pattern Q10 and the adjacent patterns Q11 and Q12 present on the outer sides of both the ends of the segment B2. It is possible to improve accuracy of a correction value for the correction target pattern Q10.

The correction target pattern Q10 includes sections having widths W0, W1, and W2. The length in the horizontal direction of the search area E2 is represented as A, the length in the vertical direction of the search area E2 is represented as S1, a space between the correction target pattern Q10 and the adjacent pattern Q11 is represented as S0, a space between the correction target pattern Q10 and the adjacent pattern Q12 is represented as S2, an overlapping distance between the imaginary segment B2′ and the side of the adjacent pattern Q11 in the section having the width W0 is represented as P0, an overlapping distance between the imaginary segment B2′ and the side of the adjacent pattern Q11 in the section having the width W1 is represented as P1, an overlapping distance between the imaginary segment B2′ and the side of the adjacent pattern Q12 in the section having the width W1 is represented as P3, an overlapping distance between the imaginary segment B2′ and the side of the adjacent pattern Q12 in the section having the width W2 is represented as P4, and a space between the adjacent patterns Q11 and Q12 is represented as P2. The correction value Bias can be given by, for example, the following Formula (2):

Bias=Bias(S0, W0)*P0/A+Bias(S0, W1)*P1/A+Bias(S1, W1)*P2/A+Bias(S2, W1)*P3/A+Bias(S2, W2)*P4/A (2)

where, Bias(S0, W0) is a bias at an interval S0 between patterns and the width W0 of the patterns, Bias(S0, W1) is a bias at the space S0 between patterns and the width W of the patterns, Bias(S1, W1) is a bias at the space S1 between patterns and the width W1 of the patterns, Bias(S2, W1) is a bias at the space S2 between patterns and the width W1 of the patterns, and Bias(S2, W2) is a bias at the space S2 between patterns and the width W2 of the patterns.

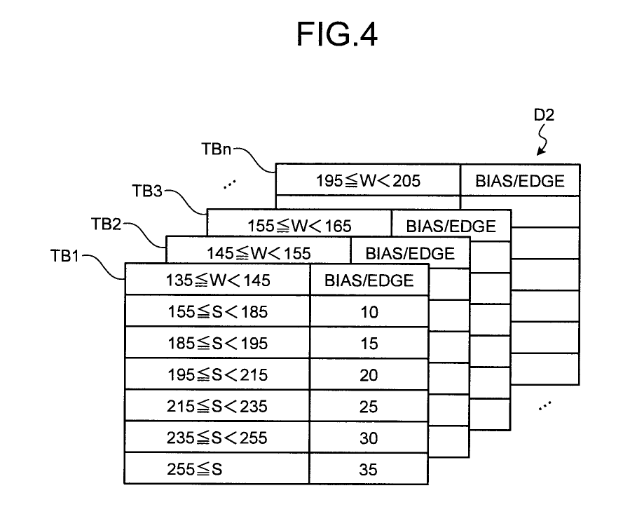

FIG. 4 is a diagram of an example of a correction table used for pattern correction processing according to an embodiment of the present invention.

In FIG. 4, in the correction table D2 shown in FIG. 1, tables TB1 to TBn in which biases corresponding to a space S between patterns are registered can be provided for each width W of the patterns. The processor 1 can extract a bias corresponding to the space S between patterns and the width W of the patterns referring to the correction table D2.

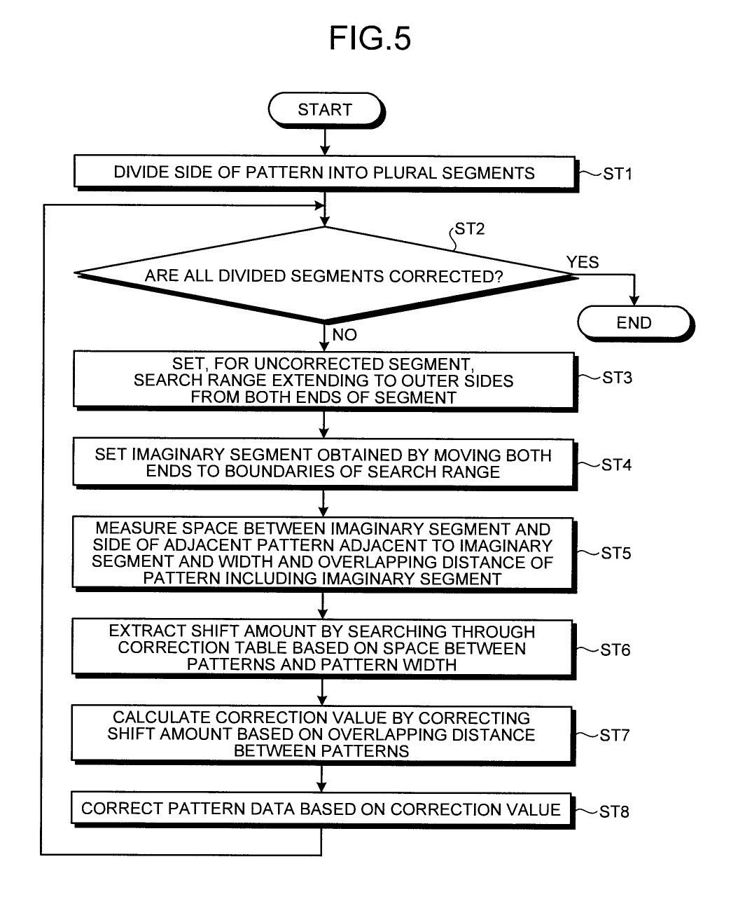

FIG. 5 is a flowchart of an example of pattern correction processing executed in the pattern correction processing apparatus shown in FIG. 1.

In FIG. 5, the processor 1 shown in FIG. 1 divides a side of a correction target pattern into a plurality of segments (step ST1). When there is an uncorrected segment (“No” at step ST2), the processor 1 sets a search area for an adjacent pattern to extend to outer sides from both the ends of the divided segment (step ST3).

Subsequently, the processor 1 sets, with respect to the correction target pattern, an imaginary segment extended from both the ends of the divided segment to boundaries of the search area (step ST4). In the search area, the processor 1 finds an adjacent pattern having a side overlapping the imaginary segment. The processor 1 measures a space between the side of the adjacent pattern and the imaginary segment, measures an overlapping distance between the side of the adjacent pattern and the imaginary segment, and measures the width of the correction target pattern for each of areas in which the imaginary segment overlaps the side of the adjacent pattern (step ST5).

The processor 1 extracts, referring to the correction table D2, a bias corresponding to the space between the imaginary segment and the side of the adjacent pattern and the width of the correction target pattern (step ST6). The processor 1 calculates a correction value for the divided segment by correcting the bias based on the overlapping distance between the imaginary segment and the side of the adjacent pattern (step ST7). The processor 1 calculates the corrected data D3 by correcting the correction target pattern based on the correction value and stores the corrected data D3 in the external storage device 4 (step ST8).

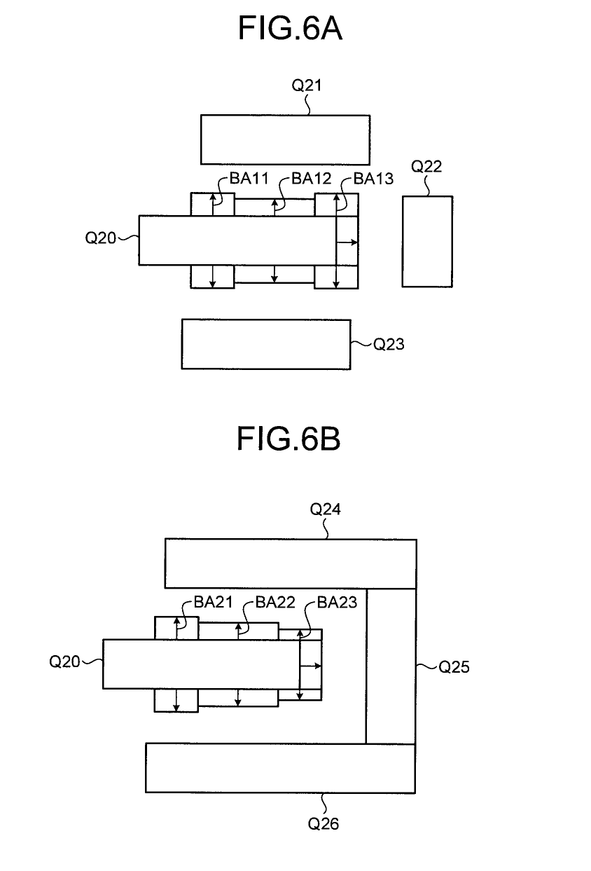

FIG. 6A is a plan view of an example of a corrected pattern according to an embodiment of the present invention.

In FIG. 6A, adjacent patterns Q21 to Q23 are arranged apart from one another to be adjacent to three sides of a correction target pattern Q20, respectively, around the correction target pattern Q20. Biases BA11 to BA13 are given to the correction target pattern Q20 according to distances between the correction target pattern Q20 and the adjacent patterns Q21 to Q23, whereby a corrected pattern is generated. When the biases BA11 to BA13 of the correction target pattern Q20 are calculated, not only a space between the correction target pattern Q20 and a pattern opposed to a segment on the correction target pattern Q20 but also a space between the correction target pattern Q20 and a pattern around the segment on the correction target pattern Q20 is taken into account. This makes it possible to set the bias BA13 taking into account spaces among the adjacent patterns Q21 to Q23 and set the bias BA13 larger than the bias BA12.

FIG. 6B is a plan view of another example of the corrected pattern according to the embodiment.

In FIG. 6B, adjacent patterns Q24 to Q26 are arranged without spaces from one another to be adjacent to the three sides of the correction target pattern Q20, respectively, around the correction target pattern Q20. Biases BA21 to BA23 are applied to the correction target pattern Q20 according to distances between the correction target pattern Q20 and the adjacent patterns Q24 and Q26, whereby a corrected pattern is generated. When the biases BA21 to BA23 of the correction target pattern Q20 are calculated, not only a space between the correction target pattern Q20 and a pattern opposed to a segment on the correction target pattern Q20 but also a space between the correction target pattern Q20 and a pattern around the segment on the correction target pattern Q20 is taken into account. This makes it possible to set the bias BA23 taking into account spaces among the adjacent patterns Q24 to Q26 and set the bias BA23 smaller than the bias BA22.

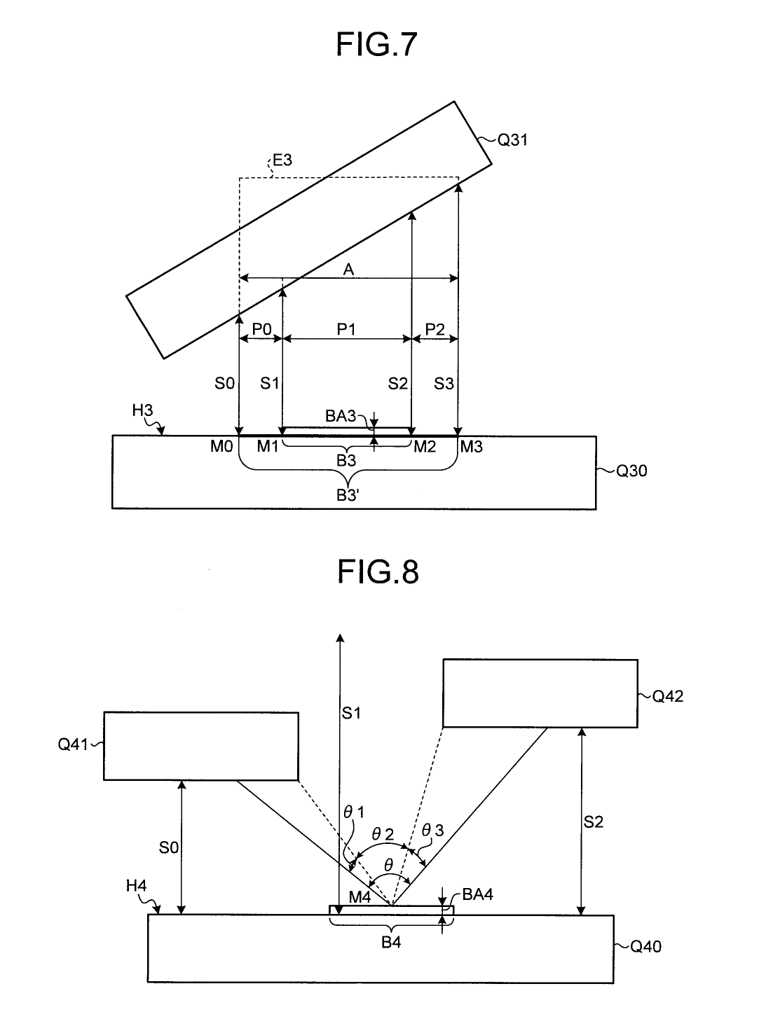

FIG. 7 is a plan view of an example of a layout of patterns for explaining pattern correction processing according to a fourth embodiment of the present invention.

In FIG. 7, an adjacent pattern Q31 adjacent to a correction target pattern Q30 is obliquely arranged around the correction target pattern Q30. In correcting the correction target pattern Q30, the processor 1 shown in FIG. 1 divides a side H3 of the correction target pattern Q30 into a plurality of segments. In calculating a correction value for a segment B3 on the side H3, the processor 1 sets a search area E3 of the adjacent pattern Q31 corresponding to the segment B3 to extend to outer sides from both the ends of the segment B3.

When the search area E3 is set, the processor 1 sets, with respect to the correction target pattern Q30, an imaginary segment B3′ extended from both the ends of the segment B3 to boundaries of the search area E3. In the search area E3, the processor 1 finds the adjacent pattern Q31 having a side overlapping the imaginary segment B3′ and measures spaces between a plurality of points of the imaginary segment B3′ and the side of the adjacent pattern Q31. For example, to measure a space between the imaginary segment B3′ and the adjacent pattern Q31, four points M0 to M3 can be set on the imaginary segment B3′.

The processor 1 extracts, referring to the correction table D2, biases corresponding to the spaces between the points of the imaginary segment B3′ and the side of the adjacent pattern Q31. The processor 1 calculates a correction value BA3 for the segment B3 based on the biases. When the adjacent pattern Q31 is obliquely arranged, as a method of correcting a bias corresponding to a space between the imaginary segment B3′ and the side of the adjacent pattern Q31, an average obtained by weighting the biases of the points with distances among the points can be used. The processor 1 calculates the corrected data D3 by correcting the correction target pattern Q30 based on the correction value and stores the corrected data D3 in the external storage device 4.

Consequently, even when the adjacent pattern Q31 is arranged obliquely to the correction target pattern Q30, it is possible to give a bias to the segment B3 on the correction target pattern Q30 while taking into account a space between the correction target pattern Q30 and the adjacent pattern Q31 present on the outer sides from both the ends of the segment B3. It is possible to improve accuracy of a correction value for the correction target pattern Q30.

The length in the horizontal direction of the search area E3 is represented as A, a space between the point M0 on the imaginary segment B3′ and the adjacent pattern Q31 is represented as S0, a space between the point M1 on the imaginary segment B3′ and the adjacent pattern Q31 is represented as S1, a space between the point M2 on the imaginary segment B3′ and the adjacent pattern Q31 is represented as S2, a space between the point M3 on the imaginary segment B3′ and the adjacent pattern Q31 is represented as S3, a distance between the points M0 and M1 on the imaginary segment B3′ is represented as P0, a distance between the points M1 and M2 on the imaginary segment B3′ is represented as P1, and a distance between the points M2 and M3 on the imaginary segment B3′ is represented as P2. The correction value Bias can be given by, for example, the following Formula (3). In this embodiment, P0, P1, and P2 are overlapping distances.

Bias=(Bias(S0)+Bias(S1))/2*P0/A+(Bias(S1)+Bias(S2))/2*P1/A+(Bias(S2)+Bias(S3))/2*P2/A (3)

where, Bias(S0) is a bias at the space S0 between patterns, Bias(S1) is a bias at the space S1 between patterns, Bias(S) is a bias at the space S2 between patterns, and Bias(S3) is a bias at the space S3 between patterns.

FIG. 8 is a plan view of an example of a layout of patterns for explaining pattern correction processing according to a fifth embodiment of the present invention.

In FIG. 8, adjacent patterns Q41 and Q42 adjacent to a correction target pattern Q40 are arranged around the correction target pattern Q40. In correcting the correction target pattern Q40, the processor 1 shown in FIG. 1 divides a side H4 of the correction target pattern Q40 into a plurality of segments. The processor 1 searches through a range of a predetermined radiation angle θ from a point M4 on the divided segment B4 and finds adjacent patterns Q41 and Q42 having sides crossing a straight line extended from the point M4 within the range of the radiation angle θ. The radiation angle θ can set the straight line extended from the point M4 to cross the sides of the adjacent patterns Q41 and Q42 in positions extending to outer sides from both ends of the segment B4.

The processor 1 measures spaces between the correction target pattern Q40 and the sides of the adjacent patterns Q41 and Q42 and measures a range of angels in which the straight line extended from the point M4 within the range of the radiation angle θ crosses the sides of the adjacent patterns Q41 and Q42.

The processor 1 extracts, referring to the correction table D2, biases corresponding to the spaces between the correction target pattern Q40 and the sides of the adjacent patterns Q41 and Q42. The processor 1 calculates a correction value for the segment B4 by correcting the biases based on the range of angles in which the straight line extended from the point M4 within the range of the radiation angle θ crosses the sides of the adjacent patterns Q41 and Q42. As a method of correcting the biases corresponding to the spaces between the segment B4 and the sides of the adjacent patterns Q41 and Q42, an average obtained by weighting the range of angles crossing the sides of the adjacent patterns Q41 and Q42 with the biases can be used. The processor 1 calculates the corrected data D3 by correcting the correction target pattern Q40 based on the correction value and stores the corrected data D3 in the external storage device 4.

Consequently, even when the adjacent patterns Q41 and Q42 are present in oblique directions of the segment B4, it is possible to give a bias to the segment B4 on the correction target pattern Q40 while taking into account spaces between the correction target pattern Q40 and the adjacent patterns Q41 and Q42. It is possible to improve accuracy of a correction value for the correction target pattern Q40.

A space between the correction target pattern Q40 and the adjacent pattern Q41 is represented as S0, a space between the correction target pattern 40 and the adjacent pattern Q42 is represented as S2, a space on the correction target pattern Q40 without an adjacent pattern is represented as S1, a range of angles crossing the side of the adjacent pattern Q41 is represented as θ1, a range of angles crossing the side of the adjacent pattern Q42 is represented as θ3, and a range of angles not crossing the sides of both the adjacent patterns Q41 and Q42 is represented as θ2. The correction value Bias can be given by, for example, the following Formula (4):

Bias=Bias(S0)*θ1/θ+Bias(S1)*θ2/θBias(S2)*θ3/θ

where, Bias(S0) is a bias at the space S0 between patterns, Bias(S1) is a bias at the space SI between patterns, and Bias(S2) is a bias at the space S2 between patterns.

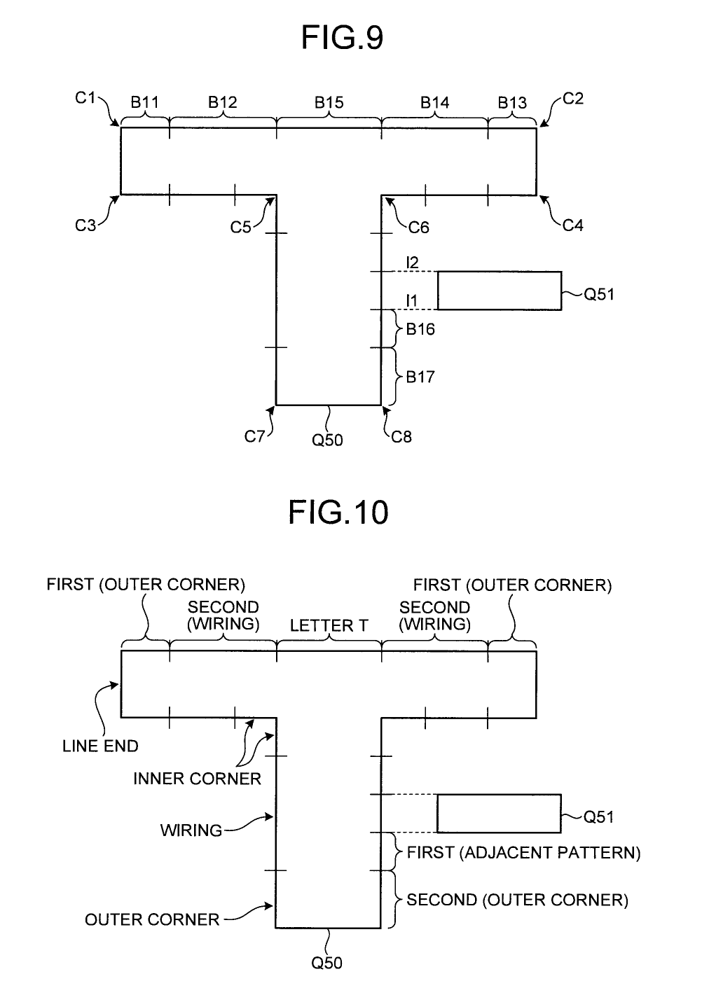

FIG. 9 is a plan view of an example of division of sides of a pattern for explaining pattern correction processing according to a sixth embodiment of the present invention.

In FIG. 9, an adjacent pattern Q51 adjacent to a T-shaped correction target pattern Q50 is arranged around the correction target pattern Q50. A plurality of corners C1 to C8 are provided in the correction target pattern Q50.

A side of the correction target pattern Q50 can be divided at length equal to or larger than a minimum design dimension from the corners C1 and C2. For example, segments B11 and B12 can be generated by dividing the side from the corner C1. Segments B13 and B14 can be generated by dividing the side from the corner C2. On a side opposed to the adjacent pattern Q51, perpendiculars 11 and 12 are drawn from corners of the adjacent pattern Q51 to the correction target pattern Q50. Segments B16 and B17 can be generated by dividing the side orthogonal to the perpendiculars 11 and 12 based on the length equal to or larger than the minimum design dimension from positions of the perpendiculars 11 and 12. When the length of the remaining side is reduced to be equal to or smaller than the minimum design dimension by the division, that section can be prevented from being divided. The division can be performed at equal intervals or lengths of divided sides can be different. When the side of the correction target pattern Q50 is divided in this way, an attribute can be set for each of the divided sides.

FIG. 10 is a plan view of an example of attributes given to segments obtained by dividing the sides of the pattern shown in FIG. 9.

In FIG. 10, segments B11 and B13 are segments divided first from the corners C1 and C2, respectively. For example, an attribute of an outer corner is set for the segments B11 and B13. Segments B12 and B14 are segments divided second from the corners C1 and C2, respectively. For example, an attribute of wiring is set for the segments B12 and B14. An attribute of a letter T is set for a segment B15 in a section at the end of the center line of T. A segment B16 is a segment divided first from the perpendicular 11. For example, an attribute of an adjacent pattern is set for the segment B16. A segment B17 is a segment divided second from the perpendicular 11. For example, an attribute of an outer corner is set for the segment B17. An attribute of an inner corner is set for segments divided first from the corners C5 and C6 shown in FIG. 9, respectively. For example, an attribute of a line end is set for a segment between the corners C1 and C3.

For each of the divided sides, the width of the correction target pattern Q50 and a space and an overlapping distance between the correction target pattern Q50 and the adjacent pattern Q51 adjacent to the correction target pattern Q50 are measured in a plurality of places. A direction of the measurement of the width, the space, and the overlapping distance can be decided for each of the attributes. A bias is set to 0 for the segments for which the attribute of the letter T is set and the segments for which the attribute of the line end is set. These segments are prevented from moving.

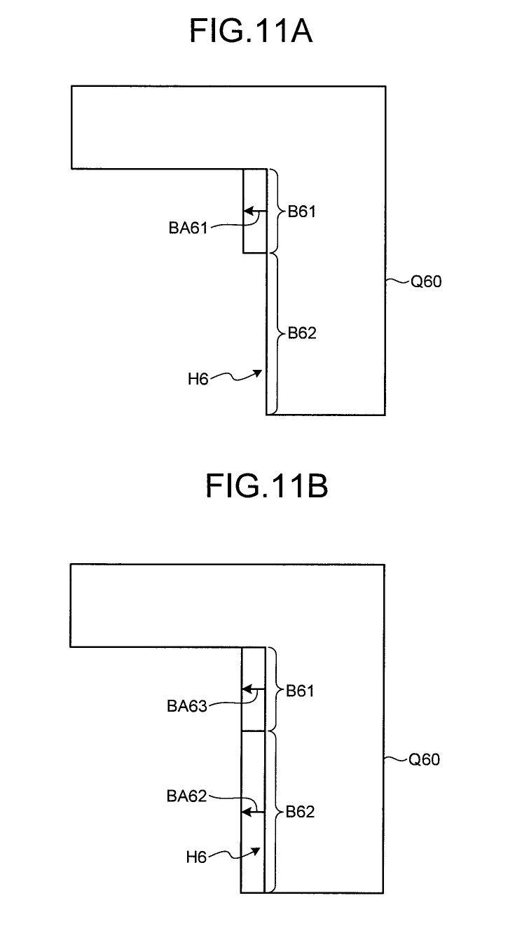

FIG. 11A is a plan view of an example of pattern correction processing executed when an attribute of an inner corner is given to a segment according to a seventh embodiment of the present invention. FIG. 11B is a plan view of another example of the pattern correction processing executed when the attribute is given to the segment according to the seventh embodiment.

In FIG. 11A, a side H6 of an L-shaped correction target pattern Q60 is divided into segments B61 and B62. It is assumed that an attribute of an inner corner is set for the segment B61. In this case, for example, a fixed bias BA61 can be given to the segment B61 as a fixed value.

Alternatively, as shown in FIG. 11B, when a bias BA62 is given to a segment B62 adjacent to the segment B61, a bias BA62 same as the bias BA62 can be given to the segment B61.

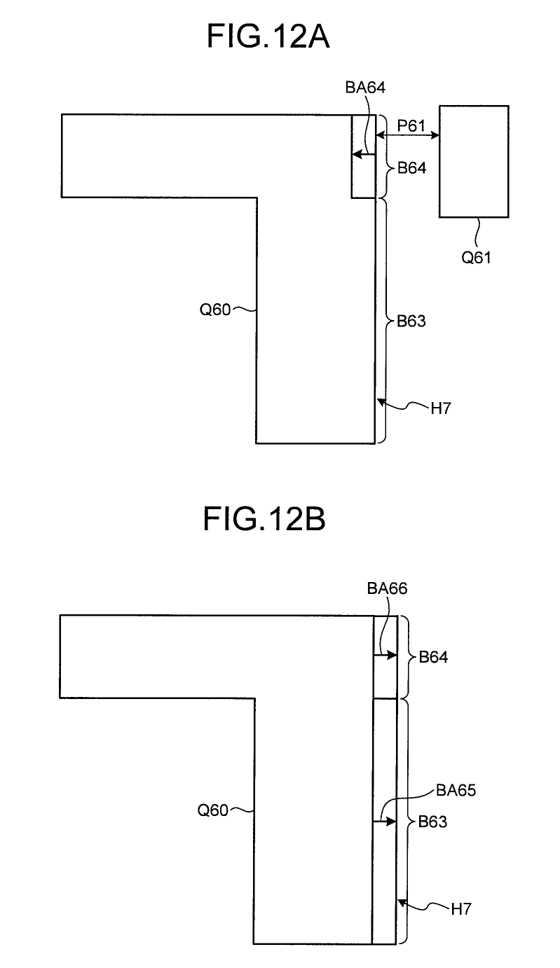

FIG. 12A is a plan view of an example of pattern correction processing executed when an attribute of an outer corner is given to a segment according to an eighth embodiment of the present invention. FIG. 12B is a plan view of another example of the pattern correction processing executed when the attribute is given to the segment according to the eighth embodiment.

In FIG. 12A, a side H7 of the L-shaped correction target pattern 60 is divided into segments B63 and B64. It is assumed that an attribute of an outer corner is set for the segment B64. An adjacent pattern Q61 is arranged adjacent to the segment B64. In this case, for example, a fixed bias BA64 can be given to the segment B64 as a fixed value. In particular, when a space P61 between the correction target pattern Q60 and the adjacent pattern Q61 is equal to or smaller than a predetermined value, the bias BA64 can be set to a negative value.

Alternatively, as shown in FIG. 12B, when a bias BA65 is given to the segment B63 adjacent to the segment B64, a bias BA66 same as the bias BA65 can be given to the segment B64.

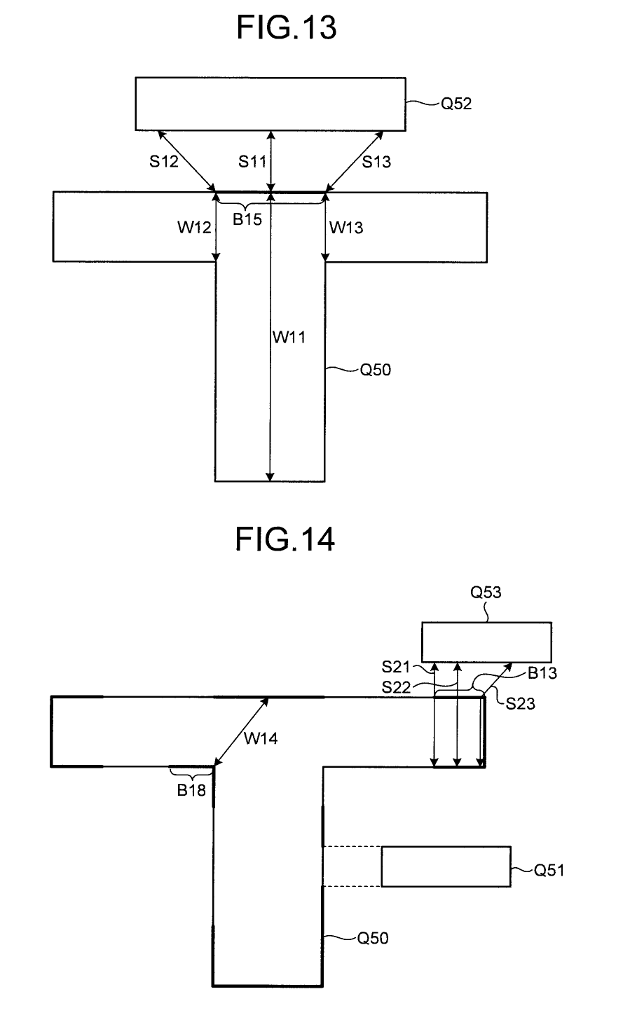

FIG. 13 is a plan view of an example of pattern correction processing executed when an attribute is given to a segment according to a ninth embodiment of the present invention.

In FIG. 13, it is assumed that an attribute of a letter T is set for the segment B15 on the correction target pattern Q50. It is assumed that the adjacent pattern Q52 is arranged adjacent to the segment B15 on the correction target pattern Q50.

When the width of a pattern corresponding to the segment B15 is measured, widths W11 to W13 of the correction target pattern Q50 can be measured, for example, at both the ends and in the center of the segment B15. When a distance from the segment B15 to the adjacent pattern Q52 is measured, distances S12 and S13 to the adjacent pattern Q52 can be obliquely measured at both the ends of the segment B15. A distance S11 to the adjacent pattern Q52 can be vertically measured in the center of the segment B15. When the distances S12 and S13 to the adjacent pattern Q52 are obliquely measured, the distance S12 can be measured at an angle of, for example, 135 degrees with respect to the segment B15. The distance S13 can be measured at an angle of, for example, 45 degrees with respect to the segment B15.

FIG. 14 is a plan view of an example of pattern correction processing executed when an attribute is given to a segment according to a tenth embodiment of the present invention.

In FIG. 14, it is assumed that an attribute of an outer corner is set for the segment B13 on the correction target pattern Q50. It is assumed that an attribute of an inner corner is set for a segment B18 on the correction pattern Q15. It is assumed that an adjacent pattern Q53 is arranged adjacent to the segment B13 on the correction target pattern Q50.

When the width of a pattern corresponding to the segment B18 is measured, for example, width W14 of the correction target pattern Q50 can be measured obliquely from an end of the segment B18. When the width W14 of the correction target pattern Q50 is obliquely measured, the width W14 can be measured at an angle of, for example, 45 degrees with respect to the segment B18.

When a distance from the segment B13 to the adjacent pattern Q53 is measured, a distance S23 to the adjacent pattern Q53 can be obliquely measured at the right end of the segment B13. Distances S21 and S22 to the adjacent pattern Q53 can be vertically measured at the left end and in the center of the segment B13. When the distance S23 to the adjacent pattern Q53 is obliquely measured, the distance S23 can be measured at an angle of, for example, 45 degrees with respect to the segment B13.

When widths of patterns and distances to an adjacent pattern are measured for the segments for which the attributes are set as explained above, a correction table is searched through according to the widths and the distances. A plurality of biases are extracted for the respective segments. A correction table in which a relation between the width and the distance is different for each of attributes can also be provided.

When the biases are extracted for the respective segments, a correction value calculation formula corresponding to the attributes of the segments is selected. A correction value for the patterns is calculated from the correction value calculation formula. The correction value can be calculated as an average obtained by weighting the biases with overlapping distances or can be calculated by weighting a maximum and a minimum of the biases with overlapping distances. The patterns of the divided segments are corrected based on the correction value calculated in this way.

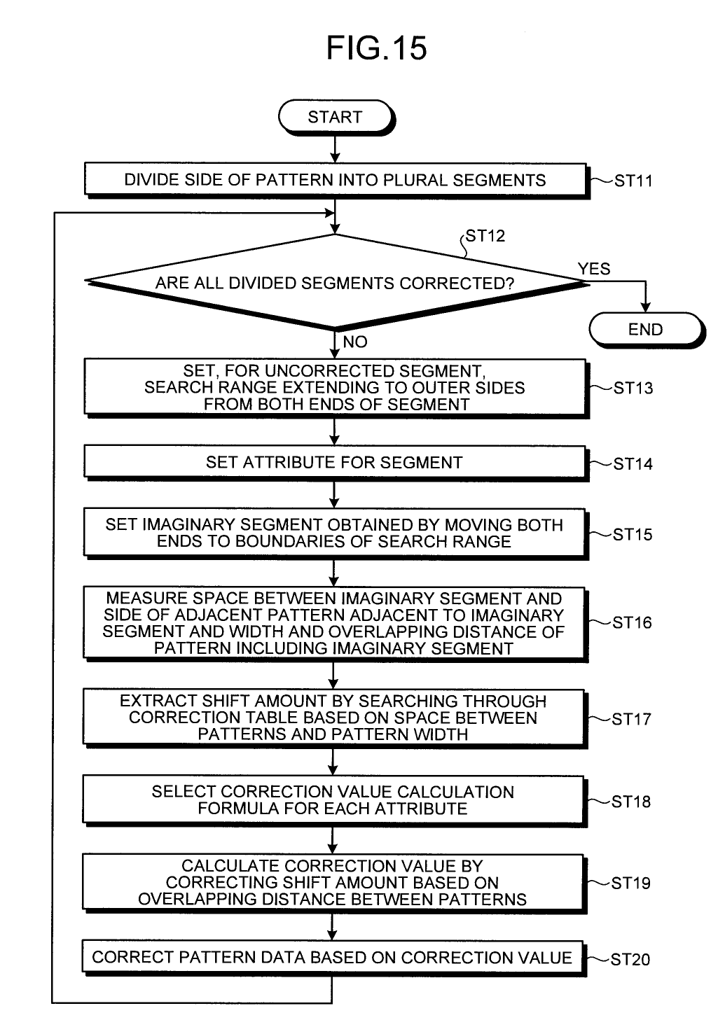

FIG. 15 is a flowchart of an example of pattern correction processing executed when an attribute is given to a segment in the pattern correction processing apparatus shown in FIG. 1.

In FIG. 15, the processor 1 shown in FIG. 1 divides a side of a correction target pattern into a plurality of segments (step ST11). When there is an uncorrected segment (“NO” at step ST12), the processor 1 sets a search area for an adjacent pattern to extend to outer sides from both the ends of the divided segment (step ST13).

Subsequently, the processor 1 sets an attribute for the divided segment (step ST14). Examples of the attribute include an inner corner, an outer corner, and a line end.

The processor 1 sets, with respect to the correction target pattern, an imaginary segment extended from both the ends of the divided segment to boundaries of the search area (step ST15). In the search area, the processor 1 finds an adjacent pattern having a side overlapping the imaginary segment. The processor 1 measures a space between the side of the adjacent pattern and the imaginary segment, measures an overlapping distance between the side of the adjacent pattern and the imaginary segment, and measures the width of the correction target pattern for each of areas in which the imaginary segment overlaps the side of the adjacent pattern (step ST16).

The processor 1 extracts, referring to the correction table D2, a bias corresponding to the space between the imaginary segment and the side of the adjacent pattern and the width of the correction target pattern (step ST17). The processor 1 selects a correction value calculation formula for each of the attributes set for the divided segments (step ST18).

For example, when an attribute set for a segment is a line end, the processor 1 can select a correction value calculation formula Bias=0. When an attribute set for a segment is an inner corner or an outer corner, the processor 1 can select a correction value calculation formula Bias=fixed value or Bias=Bias (Next Segment). Next Segment indicates a segment adjacent to a divided segment.

The processor 1 calculates a correction value for the divided segment by correcting a bias on the correction value calculation formula based on the overlapping distance between the imaginary segment and the side of the adjacent pattern (step ST19). The processor 1 calculates the corrected data D3 by correcting the correction target pattern based on the correction value and stores the corrected data D3 in the external storage device 4 (step ST20).

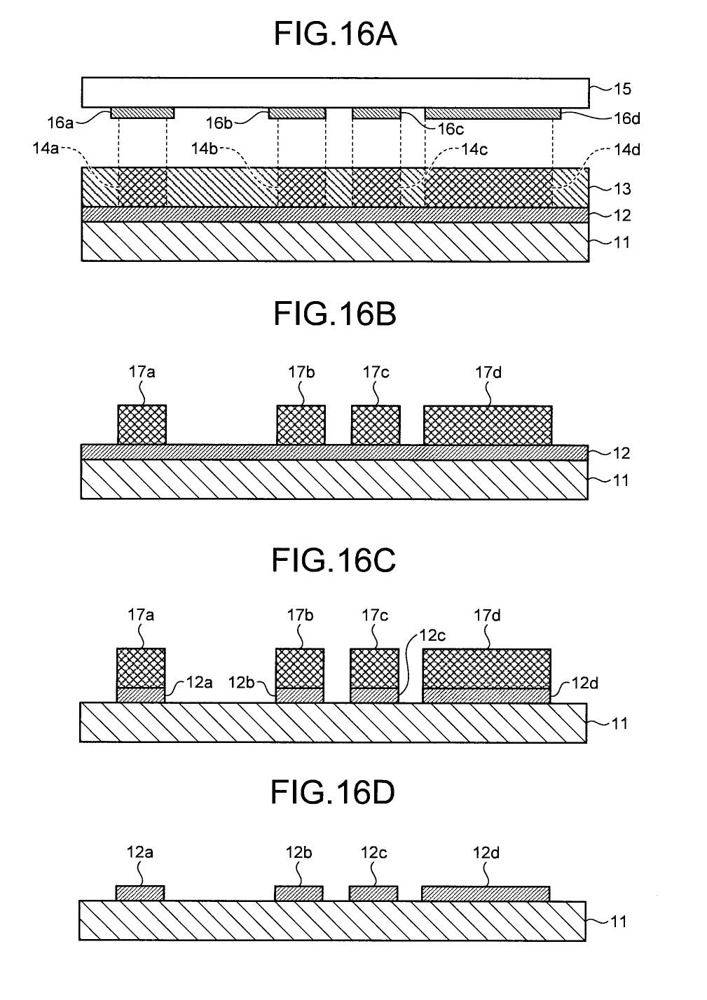

FIGS. 16A to 16D are sectional view of a method of manufacturing a semiconductor device according to an eleventh embodiment of the present invention.

In FIG. 16A, a laminated film 12 is formed on a base layer 11. A resist film 13 is formed on the laminated film 12. As the base layer 11, a semiconductor substrate, an insulating layer, a conductive layer, or the like can be used. As the laminated film 12, an insulating layer, a conductive layer, or the like can be used. An exposure mask 15 is arranged on the resist film 13. Light blocking films 16a to 16d such as Cr films or halftone films are formed on the exposure mask 15. A mask pattern can be formed by the light blocking films 16a to 16d. The light blocking films 16a to 16d are subjected to pattern correction for relaxing fluctuation in exposure intensity during photolithography due to the density of the light blocking films 16a to 16d. As the pattern correction, any one of the method shown in FIG. 2, the method shown in FIG. 3, the method shown in FIG. 7, the method shown in FIG. 8, and the method shown in FIG. 10 can be used.

When a pattern is formed on the resist film 13, exposure light is irradiated on the resist film 13 via the exposure mask 15. When the exposure light is irradiated on the resist film 13, in a positive resist, a resist in an irradiated section is resolved and latent images 14a to 14d are formed in the irradiated section.

As shown in FIG. 16B, the resist film 13 on which the latent images 14a to 14d are formed is developed, whereby resist patterns 17a to 17d are formed on the laminated film 12. As shown in FIG. 16C, the laminated film 12 is etched with the resist patterns 17a to 17d as masks to form laminated patterns 12a to 12d on the base layer 11. The laminated patterns 12a to 12d can form, for example, a wiring pattern, a trench pattern, or a contact pattern. As shown in FIG. 16D, the resist patterns 17a to 17d are removed from the laminated patterns 12a to 12d by a method such as ashing.

Because the pattern correction is applied to the light blocking films 16a to 16d, a difference occurs between a dimension of the light blocking films 16a to 16d and a dimension of the laminated patterns 12a to 12d. The dimension of the laminated patterns 12a to 12d can be matched with a dimension of a design value.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A pattern correcting method comprising:
dividing a side of a correction target pattern into a plurality of segments;
measuring a space between each of the divided segment or an imaginary segment extended from both ends of the segment to outer sides and a side of an adjacent pattern adjacent to the segment;
measuring an overlapping distance between each of the divided segment or the imaginary segment extended from both the ends of the segment to the outer sides and the side of the adjacent pattern;
extracting a shift amount of the segment corresponding to the measured space; and
calculating a correction value for the segment by correcting the shift amount based on the overlapping distance.

2. The pattern correcting method according to claim 1, wherein the side of the correction target pattern is divided into a plurality of segments at intervals equal to or larger than a minimum design dimension of a line in design data.

3. The pattern correcting method according to claim 1, wherein the correction value is a value obtained by weighting the shift amount with the overlapping distance.

4. A pattern correcting method comprising:
dividing a side of a correction target pattern into a plurality of segments;
measuring a space between each of the divided segment or an imaginary segment extended from both ends of the segment to outer sides and a side of an adjacent pattern adjacent to the segment;
giving attributes to the divided segment;
measuring an overlapping distance between each of the divided segment or the imaginary segment extended from both the ends of the segment to the outer sides and the side of the adjacent pattern;
extracting a shift amount of the segment corresponding to the measured space;
selecting a correction value calculation formula corresponding to each of the attributes; and
calculating a correction value for the segment by correcting the shift amount on the correction value calculation formula based on the overlapping distance.

5. The pattern correcting method according to claim 4, wherein a measuring direction of the space and the overlapping distance is set for each of the attributes.

6. The pattern correcting method according to claim 4, wherein the attribute is an outer corner, an inner corner, wiring, a letter T, or a line end.

7. The pattern correcting method according to claim 6, wherein a shift amount of a segment to which the attribute of the letter T or the line end is given is set to 0.

8. The pattern correcting method according to claim 6, wherein a shift amount of a segment to which the attribute of the outer corner or the inner corner is given is set to a fixed value.

9. A pattern correcting method comprising:
dividing a side of a correction target pattern into a plurality of segments;
measuring a space between each of the divided segment or an imaginary segment extended from both ends of the segment to outer sides and a side of an adjacent pattern adjacent to the segment and line width of the segment;
measuring an overlapping distance between each of the divided segment or the imaginary segment extended from both the ends of the segment to the outer sides and the side of the adjacent pattern;
extracting a shift amount of the segment corresponding to the measured space and the measured line width; and
calculating a correction value for the segment by correcting the shift amount based on the overlapping distance.

10. The pattern correcting method according to claim 9, wherein the shift amount corresponding to the space and the line width is extracted by referring to a correction table including, for each width of patterns, a table in which a shift amount corresponding to a space between the patterns is registered.

11. A pattern correcting method comprising:
dividing a side of a correction target pattern into a plurality of segments;
finding, in a range of a predetermined radiation angle from a point on the segment, a side of an adjacent pattern adjacent to each of the divided segment;
measuring a space between the found side of the adjacent pattern and the segment;
extracting a shift amount corresponding to the measured space; and
calculating a correction value for the segment by correcting the shift amount based on a range of angle formed by segments crossing the found side of the adjacent pattern among segments extended in the range of the predetermined radiation angle from the point on the segment.

12. A method of manufacturing a semiconductor device comprising:
dividing a side of a correction target pattern into a plurality of segments;
measuring a space between each of the divided segment or an imaginary segment extended from both ends of the segment to outer sides and a side of an adjacent pattern adjacent to the segment;
measuring an overlapping distance between each of the divided segment or the imaginary segment extended from both the ends of the segment to the outer sides and the side of the adjacent pattern;
extracting a shift amount of the segment corresponding to the measured space;
calculating a correction value for the segment by correcting the shift amount based on the overlapping distance; and
transferring, using a mask formed based on a mask pattern corrected based on the correction value, the mask pattern onto a semiconductor substrate.

13. The method of manufacturing a semiconductor device according to claim 12, wherein the side of the correction target pattern is divided into a plurality of segments at intervals equal to or larger than a minimum design dimension of a line in design data.

14. The method of manufacturing a semiconductor device according to claim 12, wherein the correction value is a value obtained by weighting the shift amount with the overlapping distance.

15. The method of manufacturing a semiconductor device according to claim 12, wherein a measuring direction of the space and the overlapping distance is set for each of attributes of the segments.

16. A pattern correcting program for correcting, based on an overlapping distance between a segment on a correction target pattern and a side of an adjacent pattern adjacent to the segment or an imaginary segment extended from both ends of the segment to outer sides, a shift amount determined depending on a space between the segment or the imaginary segment extended from both the ends of the segment to the outer sides and the side of the adjacent pattern to thereby calculate a correction value for the segment.

17. The pattern correcting program according to claim 16, wherein the side of the correction target pattern is divided into a plurality of segments at intervals equal to or larger than a minimum design dimension of a line in design data.

18. The pattern correcting program according to claim 16, wherein the correction value is a value obtained by weighting the shift amount with the overlapping distance.

19. The pattern correcting program according to claim 16, wherein a measuring direction of the overlapping distance is set for each attribute of the segment.

20. The pattern correcting program according to claim 16, wherein the attribute is an outer corner, an inner corner, wiring, a letter T, or a line end.
